(19) United States
(12) Patent Application Publication
(10) Pub. No.: US 2014/0301797 A1
(43) Pub. Date: Oct. 9, 2014

(54) Device and a Method for Machining Printed Circuit Boards

(71) Applicants: Jochem Berkmann, Eppertshausen (DE); Bernd Fokuhl, Rauschenberg (DE); Markus Winterschladen, Kahl (DE)

(72) Inventors: Jochem Berkmann, Eppertshausen (DE); Bernd Fokuhl, Rauschenberg (DE); Markus Winterschladen, Kahl (DE)

(73) Assignee: SKYBRAIN VERMOGENSVERWALTUNGS GMBH, Rodermark (DE)

(21) Appl. No.: 14/218,222

(22) Filed: Mar. 18, 2014

(30) Foreign Application Priority Data
Mar. 19, 2013 (DE) 102013004679.3

(51) Int. Cl. B23Q 17/22; B23B 41/00; H05K 3/40; B23B 49/00

(52) U.S. Cl. CPC B23Q 17/22; B23B 49/00; B23B 41/00; H05K 3/4038; B23B 2228/10; B23B 2251/52; H05K 2203/0207
USPC 408/1 BD; 408/125; 408/16

(57) ABSTRACT

The invention relates to a device and to a method for machining, in particular, drilling printed circuit boards (PCB) having several conductive layers (Ln). The device has a drilling spindle (2) bearing an interchangeable drilling tool (1). The drilling tool (1) has a lateral surface that has a non-conducting layer (9) at least in sections, and a core (8) that is conductive at least in sections.

The invention relates to a device and a method for machining, in particular, for drilling printed circuit boards having several conductive layers using a drilling spindle bearing an interchangeable drilling tool. Further, the invention relates to a method for machining printed circuit boards, in particular, by using such a device.

Multilayered printed circuit boards are provided not only with through bore-holes, but also because of the higher degree of utilization, to a large degree, they are also provided with drilled blind holes, which extend from the surface up to a certain conductive layer in the interior of the printed circuit board. Because of the increasing miniaturization, and thus decreasing layer thickness, a tolerance of just a few μu is required of the depth of the blind holes (measured relative to the circuit board surface). In the past, attempts had been made to meet this requirement by equipping the drill head with a calibration unit, and in addition to the measurement unit for the infeed of the drill head, it was equipped with a second measurement unit for depth. Hereby, after being placed into the tool, the drill head passes over the calibration unit, lowers and gives a zero impulse to the second measurement system, by means of which the control system identifies the respective position of the tip of the tool relative to the surface of the printed circuit board. However, here, the precision of the drilling depth is affected by imprecisions of the drilling spindle, the z-axis advance, the CNC, the feeder plate, the mechanical mounting of the second depth measurement unit and the drilling tool (for example, because of thermal expansion), as well as by any unevenness of the printed circuit board material, environmental influences (for example, contaminations) and machine maintenance. Moreover, the mechanical effort due to the additional measurement unit and the calibration unit that contains, for example, a laser, is relatively large.

From DE 43 40 249 A1, a device is known for depth drilling of printed circuit boards in which a drilling spindle bearing a drilling tool can be lowered in the direction of a conductive surface layer of a printed circuit board located on a machine table and the respective height adjustment of the drilling tool can be measured relative to the printed circuit board surface by means of a height measurement unit, whereby between the drilling tool and the conductive surface layer or the n^{th} conductive layer, a voltage difference is generated, and the signal that can be tapped upon contact by the tip of the drilling tool with the surface layer between the drilling tool and the conductive surface layer is used to determine the zero level of the drilling depth and, if necessary, the signal that can be tapped upon contact of the tip of the drilling tool with the conductive layer for determining the end level of the drilling depth. This system is very reliable and precise; however, it is associated with an increased effort in order to associate a voltage with each individual conductive layer.

It is the objective of the present invention to propose a unit of the type cited at the beginning, as well as a method for machining conductive layers that permit a high degree of drilling precision with a simpler set-up.

According to the invention, this problem is solved by a device of the type cited at the beginning essentially thereby, that the drilling tool has a lateral surface that is provided with a non-conductive layer at least in sections, and has a core that is conductive at least in sections. In other words, the invention is based on a coated tool with a non-conductive surface. In a first machining step, when the tool is first provided with the non-conductive coating in its entirety, the core of the drilling tool can subsequently be finished at the cutting edge of the tool (core), in order to remove this coating. After that, perhaps the tip of the cutting edge of the tool is provided with a conductive coating this time, in order to seal the transition between hard metal and non-conductive coating. This leads to an improved protection against premature wear.

The present invention is based on the idea that a non-conductive coating insulates the drilling tool with respect to the conductive layers that have already been drilled. In other words, regardless of whether, and perhaps how many conductive layers have already been drilled by the tool, a measurement between the tip of the drilling tool and a conductive layer that comes in contact with the tip of the drilling tool can be made. Thereby, it is no longer required to provide each individual conductive layer with a certain voltage; rather all conductive layers can have the same voltage or even different voltages. In order to capture the tip of the drilling tool relative to the positions of the printed circuit board, an insulating layer must be present between the layers of the printed circuit board in the direction of the drill advance. Advantageously, this can be an air layer, i.e. the layers have a very small distance with respect to each other.

When in the lateral surface and/or in a conical surface of the drilling tool that faces away from the drilling spindle, a pocket or a similar deepening and/or a protrusion for fastening the non-conductive coating and/or the conductive coating is provided, the connection between the coating(s) can be improved. In this way, a coating can cling to the drilling tool and prolong downtimes.

Alternatively, it is also possible to first apply a conductive coating to the drilling tool and then coat it, at least in the area of the lateral surface, with the non-conductive coating.

As an alternative to coating the drilling tool, it, or at least its lateral surface, can consist entirely of a non-conductive material, whereby a conductive wire is integrated into the drilling tool up to the core (culling edge)

Preferably, the drilling spindle can be lowered in the direction of the conductive layers of a printed circuit board located on a machine table, whereby between the drilling tool and the n^{th} conductive layer, a voltage difference ΔV is generated. The signal that can be tapped upon contact by the tip of the drilling tool with the n^{th} conductive layer can thereby be used to determine the drilling depth and/or to determine the position of the n^{th} conductive layer within the printed circuit board.

It is preferred when the drilling tool is charged with a voltage of Vd≠0 volt and the conductive layers with a voltage of Vn of 0 volt. In other words, all positions of the printed circuit board are grounded. But the device and the method also work when the individual layers have charged themselves, for example, as the result of a capacitor effect.

Voltage Vd of the drilling tool can be applied by a direct mechanical contact of the tool rotor, for example, by means of an electrode. Advantageously, however, voltage Vd can be applied to the drilling tool inductively or capacitatively, i.e. without contact.

Most of the time, the printed circuit board has a surface layer (entry) for machining. In order to also capture its position, it can likewise be grounded or have a defined voltage that is different from the voltage Vd of the drilling tool. The voltage Ve of the conductive surface layer can either be established by direct contact, but in an advantageous embodiment of the invention it is generated thereby, that a blank holder associated with the drilling spindle that consists of conductive material such as metal and can be lowered to the surface layer and contact it, is charged with a voltage Ve.

In known units, the contact between the drilling tool and the respective conductive layer is generally captured with a contact drilling module. According to the invention, between the contact drilling module and the drilling device, an additional circuit board that has a microprocessor can be interspersed, which processes the signals. In other words, the drilling tool and the conductive layers are connected with a control unit that has at least one microprocessor that is equipped to analyze the voltage difference ΔV. However, it is generally not required to provide such a microprocessor. Rather, an analysis using suitable software is possible in the drive control system or the CNC.

When the drilling spindle has a drive for lowering to the printed circuit board that is connected with the control unit, the drive can be actuated depending on the voltage difference ΔV that was detected by the microprocessor. This corresponds to an online function in which the machine works as a depth drilling machine and can stop at, or after the n^{th} layer in a defined manner. For this purpose, the microprocessor works together with the drive servo of the drilling tool.

But the data capture can also be performed by the microprocessor, CNC and an external data preparation (e.g. analysis/database) at a different level, in order to determine the topography of all layers in a measurement function.

Hereby, each layer can be illustrated as a single surface. This can be done solely within the microprocessor or the control unit. Alternatively, a display unit can be associated with the control unit, with which the position of the conductive layers can be displayed depending on the voltage difference ΔV that was detected by the microprocessor.

In the device according to the invention, a height measurement unit can also be provided, by means of which the respective height of the drilling tool relative to the surface of the printed circuit board can be measured. Preferably, this height measurement is coupled with the control unit in such a way that together with the analyzed signals of the voltage difference ΔV, the aforementioned measurement function and/or the online function are made possible.

The measurement principle according to the invention is not limited to drilling, but can likewise be applied to milling or similar material finishing. When “drilling” is addressed in what has been said previously and in the following, this shall therefore not represent a limitation to this term

As the fast rate of advance of the drilling tool presents certain difficulties relative to braking the advance fast enough when the braking process is started only upon contact by the tip of the drilling tool with the n^{th} conductive layer, up to which the blind hole is to reach, according to a refinement of the invention, it is proposed that for a pre-determination of the possible position of depth of the n^{th} conductive layer, to first drill a test bore. In the subsequent depth drilling, the advance speed of the drilling tool is then switched to a lower setting at a smaller distance prior to reaching the surface of the n^{th} conductive layer (the approximate depth position that is now known) so that the “brake path” upon contact with the tip of the drilling tool with the n^{th} conductive layer is sufficiently short.

As the depth position of the n^{th} conductive layer within the printed circuit board varies because of manufacturing tolerances, as a result of which the depth drilling precision can be affected, it is provided in a still further embodiment of the invention that for each depth drilling, the depth position determined in the previous depth drilling of the n^{th} conductive layer is taken into consideration when switching the advance rate to a lower setting directly prior to reaching the n^{th} conductive layer. Hereby, the experience is utilized that the depth position of the conductive layers within the printed circuit board does not change erratically, but only gradually. In this way, in the respectively next depth drilling the depths position at which the neighboring blind hole ended is taken into consideration.

Aside from the advantages already explained (avoidance of many factors influencing the precision of depth drilling) with the solution according to the invention, an automatic z-axis adjustment and the speed advantage that is connected with such is achieved, further, monitoring of any drill failure is possible.

The objective of the present invention is also solved by a method for machining several conductive layers that lie above each other by means of an interchangeable drilling tool, that has conductive sections and non-conductive sections, whereby between the drilling tool and the n^{th} conductive layer, a voltage difference ΔV is generated, and whereby the signal that is tapped upon contact of the tip of the drilling tool with the n^{th} conductive layer is used for determining the drilling depth and/or for determining the position of the n^{th} conductive layer. Preferably, a device of the type cited above is used to implement the method.

The determination of the position of the tip of the drilling tool relative to the respective position of the conductive layer can be accomplished thereby, that either the advance of the drilling tool, or simply the time is measured, and simultaneously, a change of the signal of the drilling tool is measured that occurs respectively upon contact of the tip of the drilling tool with a conductive, for example, grounded position of the printed circuit board, and also upon leaving this position, so that the contact with the voltage of the respective position is either established or interrupted again by means of the conductive drilling tool. If the voltage curve is graphed (see FIG. 4), upon each contact of the tip of the drilling tool with a conductive, for example, grounded position of the printed circuit board, there is an erratic change in the voltage curve, and when the tip of the drilling tool leaves the conductive, for example, grounded position of the printed circuit board again, a reverse erratic change in the voltage curve. But this change is not as erratic as upon contact with a position, because upon flint extraction, a certain delay can occur.

The method according to the invention makes it possible to open up various other topics going beyond finishing such as drilling, for example, an analysis of the layer structure to examine the lamination, or a new process for back panel drilling.

The process of the method according to the invention for a multilayer measurement or a finishing provides for the following steps: drilling or pecking (i.e. multiple drilling at great thickness), capturing of measurement data, the identification of the individual levels by x and y coordinates (either in measurement mode or in online mode), review of the individual data sets for feasibility, the comparison of the datasets of a production loss, generation and preparation of surfaces and the evaluation of a drilling program.

Additional goals, features, advantages and possibilities of application of the invention result from the following description of exemplary embodiments with the aid of the drawing. Thereby, all described and/or illustrated features by themselves or in any combination form the subject matter of the invention, even independent of their summary in the claims or their reference.

Schematically shown are:

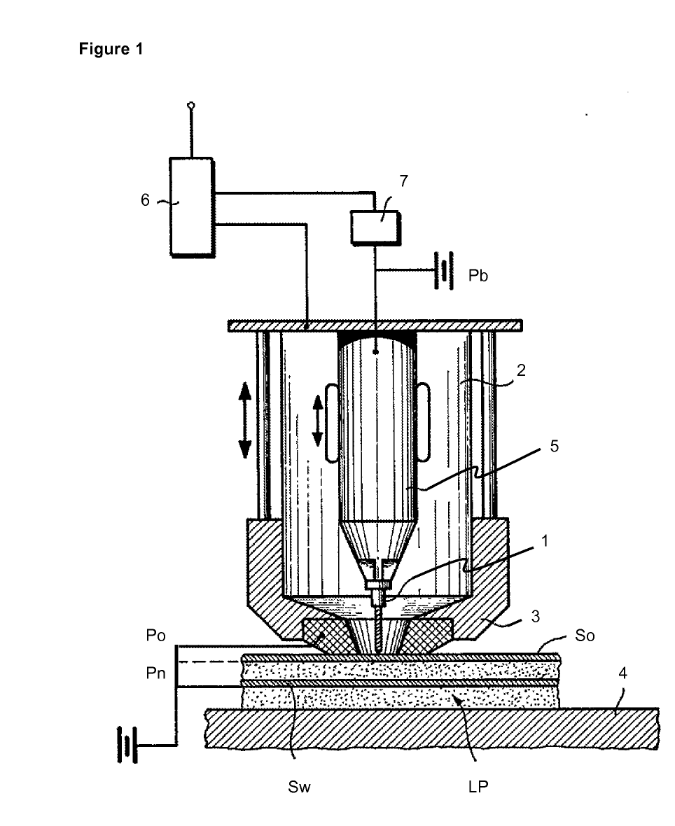

FIG. 1 shows a drilling device featuring the invention in a vertical cross section.

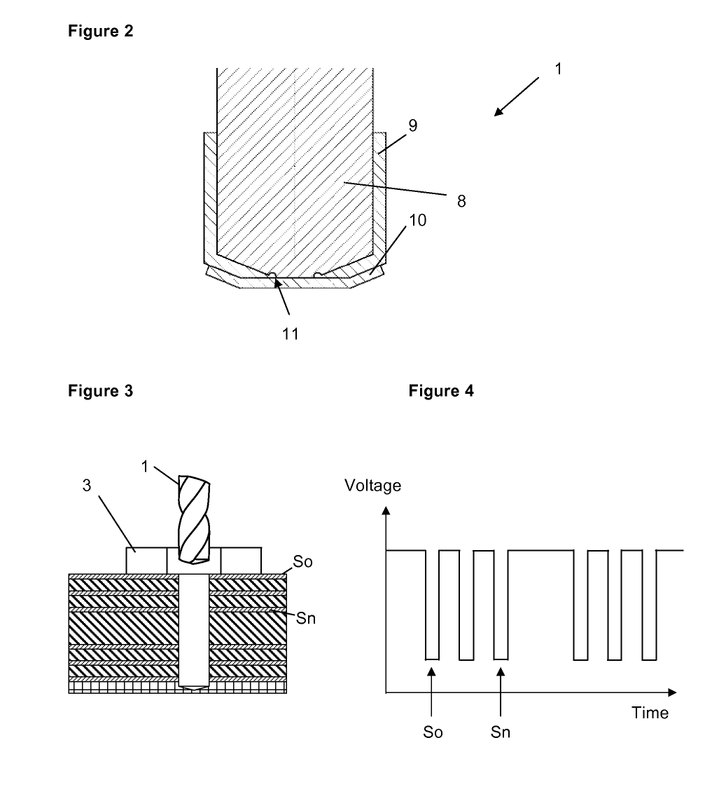

FIG. 2 shows a drilling tool according to a preferred embodiment in vertical cross section.

FIG. 3 shows a part of a drilling tool with a printed circuit board in vertical cross section, and

FIG. 4 shows an example of the voltage curve while drilling through the multi-layered printed circuit board according to FIG. 3.

A printed circuit board PCB is located, if required isolated, on a machine table 4 that is as level as possible and as much as possible, provided with a horizontal surface. The printed circuit board PCB is illustrated, for example, with two conductive layers, the conductive surface layer Le and the n^{th} conductive layer Ln. Most of the time, there is a layer of air between the two conductive layers Le, Ln and under the n^{th} conductive layer Ln, alternatively, FIG. 1 shows insulating layers. Above printed circuit board PCB, a drilling spindle 2 is mounted rotatable and adjustable in height, in which a drilling tool 1 is retained by means of a tool rotor 5. Either drilling spindle 2 and/or tool rotor 5 is/are electrically insulated.

In this special embodiment of the invention, drilling spindle 2 is associated with a metallic, i.e. conductive blank holder 3, which is lowered to the conductive surface layer Le of the printed circuit board PCB prior to the start of depth drilling. The height adjustment of drilling spindle 2 or tool rotor 5 and thus drilling tool 1 is measured by means of a height measurement unit 6.

According to the invention, between drilling tool 1 and the conductive surface layer Le and the n^{th} conductive layer Ln, a difference in voltage ΔV is generated thereby, that drilling spindle 2 is charged, for example, with a voltage Vd of v volt (v≠0), the surface layer Le or blank holder 3 that is in contact with it, with a voltage Ve and the n^{th} conductive layer Ln with a voltage of Vn, whereby Ve and Vn can be equal, for example, 0 volt, i.e. all layers are grounded. If the tip of drilling tool 1 contacts the surface layer Se at the start of depth drilling, a signal can be tapped between drilling tool 1 and the surface layer Le, which can be supplied to a signal analysis unit 7 of a control unit that is not shown in further detail, to determine the zero level of the drilling depth by height measurement unit 6. From then on, upon advancing drilling tool 1 during depth drilling, the height adjustment of drilling spindle 2 or of tool rotor 5 is continually measured by height measurement unit 6, for example, until reaching a targeted depth at which the advancement of drilling tool 1 is switched off.

When the n^{th} conductive layer Ln, which is to be reached by the blind hole has a voltage Vn≠Vd, upon the tip of drilling tool 1 contacting the n^{th} conductive layer Ln, a signal can be tapped between these two components, and for a better determination of the final level of the drilling depth, supplied to height measurement unit 6, whereupon the advance of drilling tool 1 is stopped. In this way, the desired depth of the blind hole can be achieved with high precision.

The drawing schematically illustrates a mechanical contact of tool rotor 5 for charging with a voltage Vd. The voltage Vd can, however, also be applied to drilling tool 1 inductively or capacitatively.

FIG. 2 shows drilling tool 1 in an enlarged view. Core 8 of drilling tool 1 can be seen consisting of a conductive material, usually a hard metal, and a non-conductive coating 9, that is applied to the outer lateral surface and a part of a conically tapered tip (cutting edge) in FIG. 2 on the bottom of drilling tool 1, and thereby insulates conductive core 8 toward the outside. In the lowest section of the tip (cutting edge) in FIG. 2 of drilling tool 1, the non-conductive coating 9 is replaced by a conductive coating 10. Alternatively, instead of the conductive coating 10, the non-conductive coating 9 can simply be removed in this section. A further possibility consists of first applying a conductive layer to the drill and then a non-conductive layer and subsequently to again remove the non-conductive layer at the front at the cutting edge of the tool (core), without, however, completely removing the conductive layer.

In core 8 in the proximity of the lower tip in FIG. 2, a surrounding pocket 11 is provided to which the non-conductive coating 9 clings. Instead of surrounding pocket 11 or in addition to it, individual recesses can also be provided, Alternatively, at least one protrusion can be present at the cutting edge.

FIG. 3 shows a bore hole made by a drilling tool 1 into a multilayered printed circuit board. The non-conductive coating 9 of drilling tool 1 is not shown in FIG. 3 for reasons of clarity.

FIG. 4 shows the voltage curve over time of the voltages tapped at drilling tool 1 and the, for example, jointly grounded layers Le or Ln of the printed circuit board PCB. The steep slopes indicate the positions at which the conductive tip of the drilling tool contacts a conductive, for example, grounded position of the printed circuit board, and at which the conductive tip separates from this position and returns to the (for example, air-filled) insulated intermediate space between two panels of the printed circuit board PCB. Thus, for the position Le it can be seen how the voltage first decreases, as soon as drilling tool 1 meets the panel Le, then remains largely constant as long as drilling tool 1 remains in contact with conductive panel Le, and finally rises again, when drilling tool 1 separates from panel Le, and only still has contact with position Le via the section of drilling tool 1 that is insulated by non-conductive coating 9.

As can be seen in FIG. 4, it is possible, regardless of the advance rate of drilling tool 1, to identify each individual position simply by the change in the voltage curve and by analyzing the number of voltage changes. At an advance rate that changes while drilling a hole, the characteristic changes of the voltage curve are then perhaps closer together or are further apart.

### REFERENCE NUMBERS

1 Drilling tool

2 Drilling spindle

3 Blank holder

4 Machine table

5 Tool rotor

6 Height measurement unit

7 Signal analysis

8 Core

9 Non-conductive coating

10 Conductive coating

11 Pocket

PCB Printed circuit board

Le Surface layer [entry]

Ln n^{th} conductive layer

Vd Voltage (drill)

Ve Voltage (surface layer or blank holder)

Vn Voltage (n^{th} conductive layer)

1-10. (canceled)

11. A device for drilling printed circuit boards (PCB) having several conductive layers (Ln) using a drilling spindle bearing an interchangeable drilling tool, wherein the drilling tool has a lateral surface that is provided with a non-conductive coating at least in sections, and a core that is conductive at least in sections.

12. A device as recited in claim 11, wherein the core of the drilling tool is provided with a conductive coating.

13. A device as recited in claim 11, wherein in the lateral surface and/or in a conical surface of the drilling tool facing away from the drilling spindle, a pocket or a similar recess and/or a protrusion for attaching the non-conductive coating and/or the conductive coating is provided.

14. A device as recited in claim 11, wherein the drilling spindle can be lowered in the direction of the conductive layers (Ln) in a printed circuit board (PCB) that is located on a machine table, whereby between the drilling tool and the n^{th} conductive layer (Ln) a difference in voltage (ΔV) is generated, and whereby the signal that can be tapped when the tip of the drilling tool comes in contact with the n^{th} conductive layer (Ln) is used to determine the drilling depth and/or for determining the position of the n^{th} conductive layer (Ln) within the printed circuit board (PCB).

15. A device as recited in claim 14, wherein the drilling tool is charged with a voltage (Vd) of v volt (v≠0) and the conductive layers (Ln) with a voltage of 0 volt.

16. A device as recited in claim 14, wherein the drilling tool and the conductive layers (Ln) are connected with a control unit that has at least one microprocessor that is equipped to analyze the difference in voltage (ΔV).

17. A device as recited in claim 16, wherein the drilling spindle has a drive for lowering to the printed circuit board (PCB) that is connected with the control unit in such a way that the drive can be actuated depending on the difference in voltage (ΔV) that is detected by the microprocessor.

18. A device as recited in claim 16, wherein the control unit is associated with a display unit by means of which, based on the difference in voltage (ΔV) detected by the microprocessor, the position of the conductive layers (Ln) can be displayed.

19. A device as recited in claim 11, wherein a height measurement unit is additionally provided by means of which the respective height adjustment of the drilling tool can be measured relative to the surface of the printed circuit board (PCB).

20. A method for machining several conductive layers (Ln) that are positioned on top of each other by means of an interchangeable drilling tool that is conductive in sections and non-conductive in sections, whereby between the drilling tool and the n^{th} conductive layer (Ln) a difference in voltage (ΔV) is generated, and whereby the signal that can be tapped upon contact of the tip of the drilling tool with the n^{th} conductive layer (Ln) is used to determine the drilling depth and/or for determining the position of the n^{th} conductive layer (Ln).
